(19) United States
(12) Patent Application Publication
(10) Pub. No.: US 2026/0324479 A1
(43) Pub. Date: Oct. 15, 2026

(54) TRANSFER METHOD AND TRANSFER DEVICE

(71) Applicant: Panasonic Intellectual Property Management Co., Ltd., Osaka (JP)

(72) Inventors: JUNICHI KAMATANI, Nara (JP); TOMOTAKA FURUTA, Osaka (JP)

(21) Appl. No.: 19/468,202

(22) Filed: Feb. 3, 2026

(30) Foreign Application Priority Data
Feb. 13, 2025 (JP) 2025-021746

(51) Int. Cl. H10W 72/00; H10W 80/00

(52) U.S. Cl. CPC H10W 72/07173; H10W 72/07141; H10W 72/07178; H10W 80/163

(57) ABSTRACT

A transfer method according to an aspect of the present disclosure is for transferring an element to a front surface of a target substrate using a stamp having adhesiveness, and includes: aligning the target substrate and the element picked up on the stamp by an adhesive force of the stamp; bringing the target substrate and the stamp relatively close to each other to bring the target substrate and the element into contact with each other; and moving the target substrate and the stamp relatively in a direction along a front surface of the target substrate to separate the target substrate and the stamp from each other while the target substrate and the element are in contact with each other.

### BACKGROUND

### 1. Technical Field

The present disclosure relates to a transfer method and a transfer device.

### 2. Description of the Related Art

A technique called silicon photonics for forming an optical circuit on a silicon substrate is known. The optical circuit formed by the silicon photonics has a fine size. To form a circuit with a fine size, a method for transferring the circuit to a target substrate by pick-and-place using an adhesive stamp has been studied.

For example, PTL 1 discloses a device and a method for assembling a semiconductor device on a target substrate using micro-transfer printing.

### CITATION LIST

### PATENT LITERATURE

PTL 1: Japanese Patent No. 6453437

### SUMMARY

A transfer method according to an aspect of the present disclosure is for transferring an element to a front surface of a target substrate using a stamp having adhesiveness, and includes: aligning the target substrate and the element picked up on the stamp by an adhesive force of the stamp; bringing the target substrate and the stamp relatively close to each other to bring the target substrate and the element into contact with each other; and moving the target substrate and the stamp relatively in a direction along a front surface of the target substrate to separate the target substrate and the stamp from each other while the target substrate and the element are in contact with each other.

A transfer device according to an aspect of the present disclosure is for transferring an element to a front surface of a target substrate using a stamp having adhesiveness, and includes: a target substrate installation base on which the target substrate is installed; a stamp head having a stamp for picking up the element by an adhesive force; a frame for holding the stamp head so that the stamp faces the target substrate installation base; a position adjustment device that brings the target substrate and the stamp relatively close to each other and separate from each other; a first imaging unit that images the target substrate and the element from above the target substrate; a controller that controls the position adjustment device and the first imaging unit; and a contact detector that detects contact between the target substrate and the element, in which the controller detects not only the amount of positional deviation between the element and the target substrate based on an image captured by the first imaging unit, but also distortion information on the stamp when the target substrate and the element picked up on the stamp are in contact with each other, the controller controls the position adjustment device to bring the target substrate and the stamp close to each other by relatively moving the target substrate and the stamp to reduce the amount of positional deviation, and the controller controls the position adjustment device to relatively move the target substrate and the stamp to separate the target substrate and the stamp from each other in a direction along a front surface of the target substrate while the target substrate and the element are in contact with each other when the contact detector detects the contact between the target substrate and the element picked up on the stamp.

### BRIEF DESCRIPTION OF THE DRAWINGS

FIG. 1 is a diagram schematically illustrating a transfer device according to a first exemplary embodiment of the present disclosure;

FIG. 2 is a flowchart for illustrating a transfer method for transferring an element picked up on a stamp to a target substrate;

FIG. 3A is a schematic view for illustrating a transfer method;

FIG. 3B is a schematic view for illustrating the transfer method;

FIG. 3C is a schematic view for illustrating the transfer method;

FIG. 3D is a schematic view for illustrating the transfer method;

FIG. 3E is a schematic view for illustrating the transfer method;

FIG. 3F is a schematic view for illustrating the transfer method;

FIG. 3G is a schematic view for illustrating the transfer method;

FIG. 4 is a graph for illustrating adhesive force;

FIG. 5 is a flowchart for illustrating a transfer method of element according to a second exemplary embodiment;

FIG. 6A is a schematic view for illustrating a transfer method according to the second exemplary embodiment;

FIG. 6B is a schematic view for illustrating the transfer method according to the second exemplary embodiment;

FIG. 6C is a schematic view for illustrating the transfer method according to the second exemplary embodiment; and

FIG. 6D is a schematic view for illustrating the transfer method according to the second exemplary embodiment.

### DETAILED DESCRIPTIONS

The device and method for micro-transfer printing described in PTL 1 still have room for improvement in terms of improving production efficiency.

The present disclosure provides a transfer method and a transfer device that are capable of improving production efficiency with a simple configuration.

### Background to present disclosure

Utilization of light has been studied in fields such as high-speed communication, large-capacity communication, and sensing. In particular, a technology called “silicon photonics” has attracted attention, in which an optical circuit is formed on a silicon substrate by a complementary metal oxide semiconductor (COMS) process as with a semiconductor electronic circuit. The optical circuit formed by the silicon photonics has a fine size and a light control function. The optical circuit formed by the silicon photonics includes a light input-output unit, an optical modulator, or the like. These optical circuits are connected to each other by fine optical waveguides in the order of submicron. To cause the optical circuit to function, light from a light source such as a laser diode (LD) is usually connected to an optical input unit with high accuracy through an external transmission body such as an optical fiber. Formation of an optical circuit saving space and reducing the number of components has been studied by directly disposing an LD chip or an optical element on an optical circuit board to make an optical connection.

Additionally, a device such as a micro-LED display in which a minute chip is disposed is also known. When a micro-LED display is manufactured, a method for disposing a plurality of micro-LEDs one by one on a circuit board in pick-and-place steps is used in which the micro-LEDs are formed by dicing wafers. This kind of method causes the pick-and-place step to be repeated about several tens of thousands of times, thus causing a problem of requiring time to complete the steps and leading to an increase in manufacturing cost.

PTL 1 discloses transferring a plurality of elements to a target substrate in a single pick-and-place step using a viscoelastic stamp material to shorten time required for the step. The pick-and-place step using a stamp may cause a problem that an element held by the stamp falls off and fails to be transferred to a desired position on a target substrate when the stamp has too weak adhesive force. In contrast, the stamp having too strong adhesive force may cause a problem that an element held by the stamp fails to be successfully transferred to the target substrate. PTL 1 discloses that plasma treatment or heat treatment is performed to facilitate transfer of an element.

However, an expensive device is used to perform the plasma treatment, thus increasing manufacturing cost. During the plasma treatment, the element may fall off. The heat treatment further increases takt time. As a result, improvement in production efficiency of transfer has been difficult.

For this reason, the present inventors have studied a transfer method and a transfer device of an element that are capable of improving production efficiency with a simple configuration, and have reached the invention below.

### First exemplary embodiment

Hereinafter, preferred exemplary embodiments of the present disclosure will be described in detail with reference to the drawings. The drawings each show an X-Y-Z coordinate system that is for facilitating understanding of exemplary embodiments of the present disclosure, and that does not limit the exemplary embodiments. The X-Y-Z coordinate system includes an X-axis direction that is a width direction of transfer device D1, a Y-axis direction that is a depth direction thereof, and a Z-axis direction that is a height direction thereof. The X-axis direction, the Y-axis direction, and the Z-axis direction represent a direction parallel to an X-axis, a direction parallel to a Y-axis, and a direction parallel to a Z-axis, respectively. The X-axis direction and the Y-axis direction are orthogonal to each other. The X-axis direction and the Z-axis direction are orthogonal to each other. The Y-axis direction and the Z-axis direction are orthogonal to each other. An XY plane represents a virtual plane parallel to the X-axis direction and the Y-axis direction. An XZ plane represents a virtual plane parallel to the X-axis direction and the Z-axis direction. A YZ plane represents a virtual plane parallel to the Y-axis direction and the Z-axis direction. Each drawing shows the X-axis direction in which a +X-axis direction is indicated by an arrow, and a -X-axis direction is opposite to the +X-axis direction. Each drawing shows the Y-axis direction in which a +Y-axis direction is indicated by an arrow, and a -Y-axis direction is opposite to the +Y-axis direction. Each drawing shows the Z-axis direction in which a +Z-axis direction is indicated by an arrow, and a -Z-axis direction is opposite to the +Z-axis direction. The Z-axis direction coincides with a vertical direction or an up-down direction, for example, and the X-axis direction and the Y-axis direction each coincide with a horizontal direction or a lateral direction, for example.

The present specification and the drawings show components substantially identical in function, the components being denoted by the same reference numerals to omit duplicated description. Each drawing shows shape, thickness, length, and the like of a component that are different from actual shape, thickness, length, and the like of the component. Material of each component is not limited to material described in the present exemplary embodiments.

### General configuration

### Transfer device

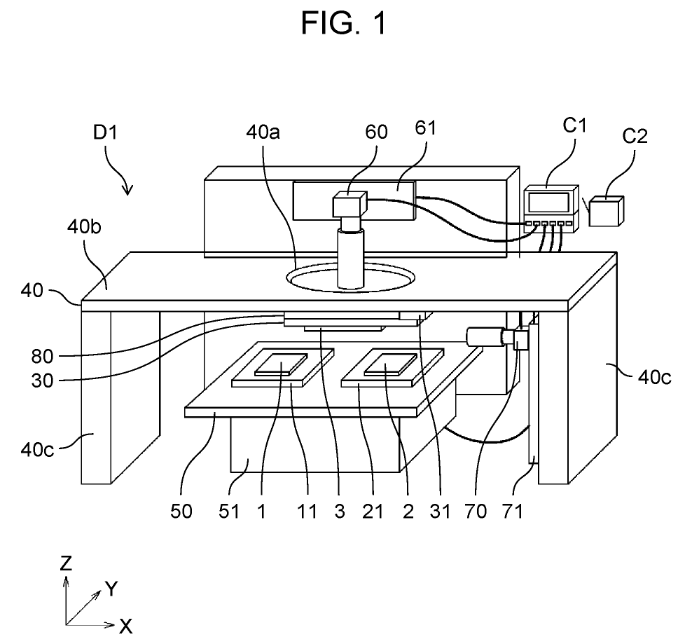

FIG. 1 is a diagram schematically illustrating transfer device D1 according to a first exemplary embodiment of the present disclosure.

As illustrated in FIG. 1, transfer device D1 includes target substrate installation base 21, stamp head 30, frame 40, a position adjustment device, first imaging unit 60, controller C1, and contact detector 80. Although transfer device D1 according to the present exemplary embodiment further includes source substrate installation base 11 and second imaging unit 70, these are not essential components of transfer device D1. The position adjustment device according to the present exemplary embodiment includes stamp head adjustment device 31 and substrate adjustment device 51.

Transfer device D1 is configured to transfer element 10 to target substrate 2 using stamp 3 having adhesiveness. Transfer device D1 according to the present exemplary embodiment picks up element 10 formed on source substrate 1 using adhesive force of stamp 3 to transfer the element to target substrate 2.

### Source substrate

Source substrate 1 is composed of a quadrangular plate-like member, for example. Source substrate 1 has a front surface provided with element 10.

Element 10 is an optical element formed on source substrate 1 through a COMS process, for example. Element 10 can be formed by an appropriate method to be able to obtain desired performance, and the method for forming the element is not limited.

Source substrate 1 and element 10 may be each provided with an alignment mark (not illustrated). The alignment mark is used to align stamp 3 and element 10 when element 10 is picked up from source substrate 1. Element 10 may be provided with coating layer 10a to protect a front surface of element 10 or to improve the adhesive force between stamp 3 and element 10. As coating layer 10a, a polymer such as a photoresist can be used, for example.

### Source substrate installation base

Source substrate installation base 11 is a member for installing source substrate 1. Source substrate installation base 11 is a quadrangular plate-shaped base, for example. Source substrate installation base 11 is not limited in type as long as it can place source substrate 1. For example, source substrate installation base 11 may be provided with a suction hole (not illustrated) for sucking source substrate 1. When negative pressure is applied to the suction hole, source substrate 1 can be brought into close contact with source substrate installation base 11.

### Target substrate

Target substrate 2 is composed of a quadrangular plate-like member, for example. Target substrate 2 has a front surface to which element 10 picked up on stamp 3 is transferred. To enable desired performance to be obtained when element 10 is transferred, target substrate 2 may be provided with an electric circuit or an optical circuit (not illustrated). Target substrate 2 may be provided with an alignment mark (not illustrated) to align element 10 and target substrate 2 when element 10 is transferred.

### Target substrate installation base

Target substrate installation base 21 is a member for installing target substrate 2. Target substrate installation base 21 is a quadrangular plate-shaped base, for example. Target substrate installation base 21 is not limited in type as long as it can place target substrate 2. For example, target substrate installation base 21 may be provided with a suction hole (not illustrated) for sucking target substrate 2. When negative pressure is applied to the suction hole, target substrate 2 can be brought into close contact with target substrate installation base 21.

Source substrate installation base 11 and target substrate installation base 21 are placed on substrate stage 50. Substrate stage 50 is supported by substrate adjustment device 51 described later. Source substrate installation base 11 and target substrate installation base 21 may be fixed to substrate stage 50 with a screw or the like, for example. Alternatively, substrate stage 50 may be formed integrally with source substrate installation base 11 and target substrate installation base 21.

### Stamp

Stamp 3 is made of a material having viscoelasticity. Stamp 3 is a member for picking up element 10 formed on source substrate 1 and transferring element 10 to a desired position on target substrate 2 by the viscoelasticity, that is, adhesive force. Stamp 3 is made of a material having viscoelasticity such as silicone rubber, for example. The material of stamp 3 is not limited to silicone rubber, and may be any material having viscoelasticity. The adhesive force of stamp 3 is appropriately set in accordance with physical properties of element 10 and target substrate 2.

Stamp 3 may be made of a transparent material, for example. When stamp 3 is made of a transparent material, element 10 to be picked up on stamp 3 and element 10 having been picked up on stamp 3 can be observed from above stamp 3 in the Z-axis direction. This configuration enables facilitating alignment when element 10 is picked up onto stamp 3 and when element 10 having been picked up is transferred to target substrate 2.

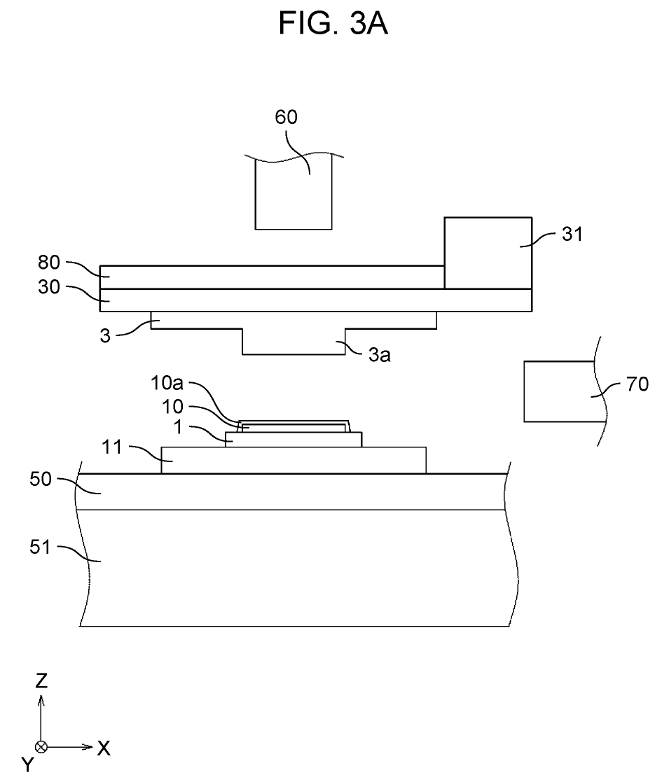

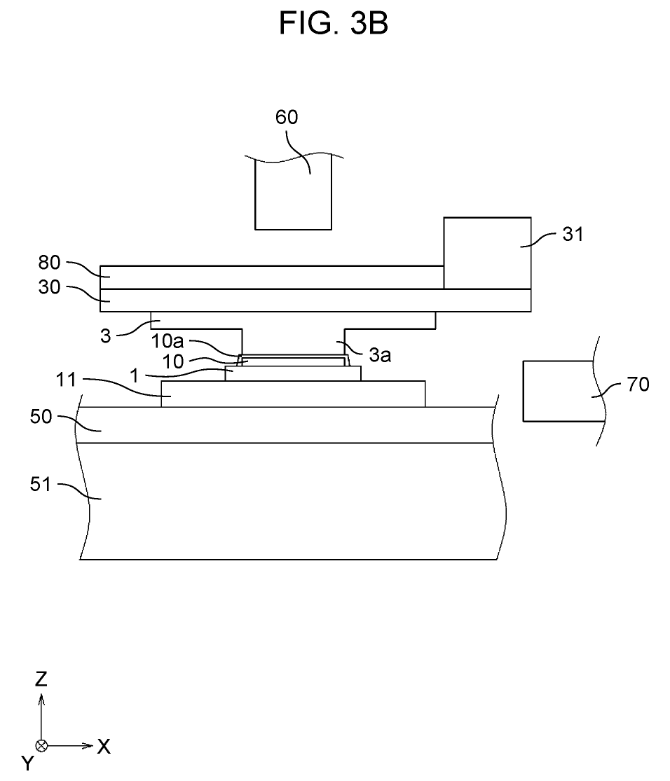

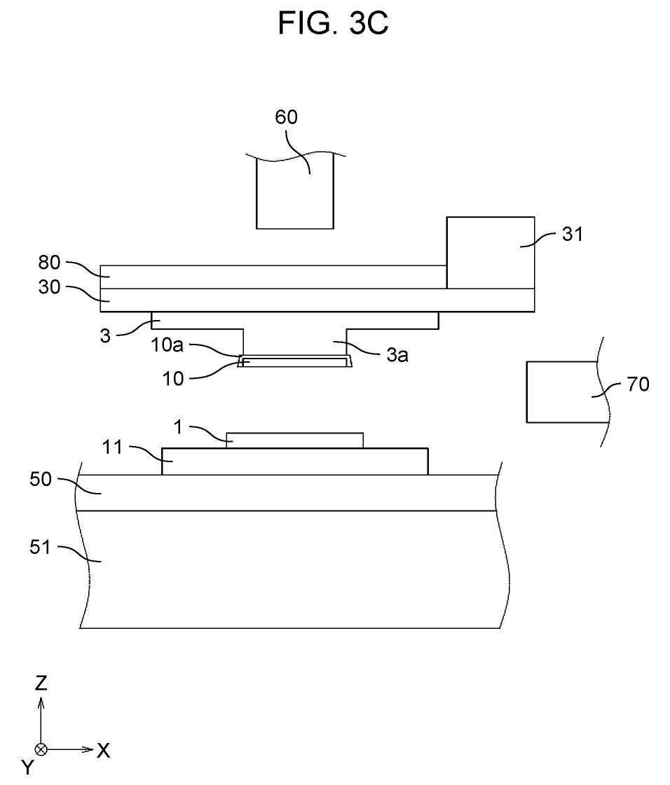

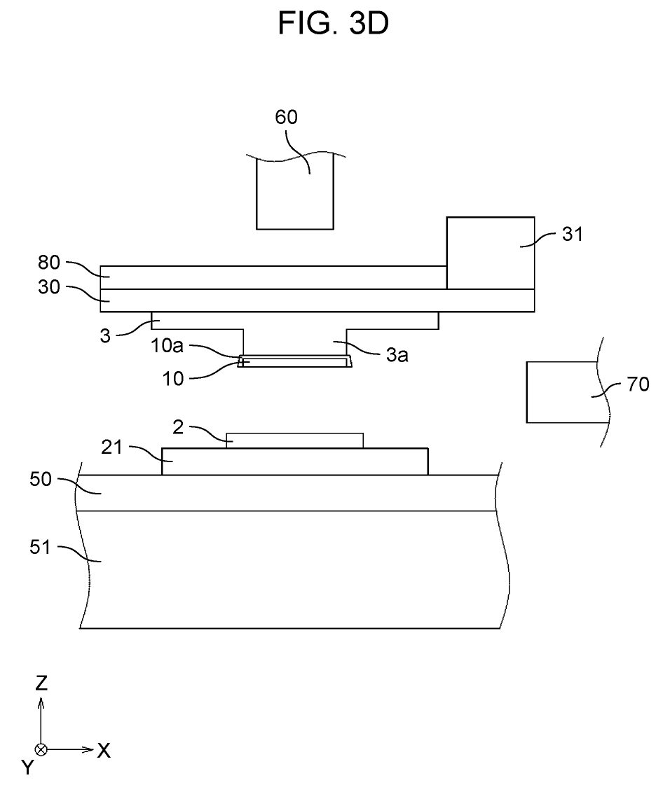

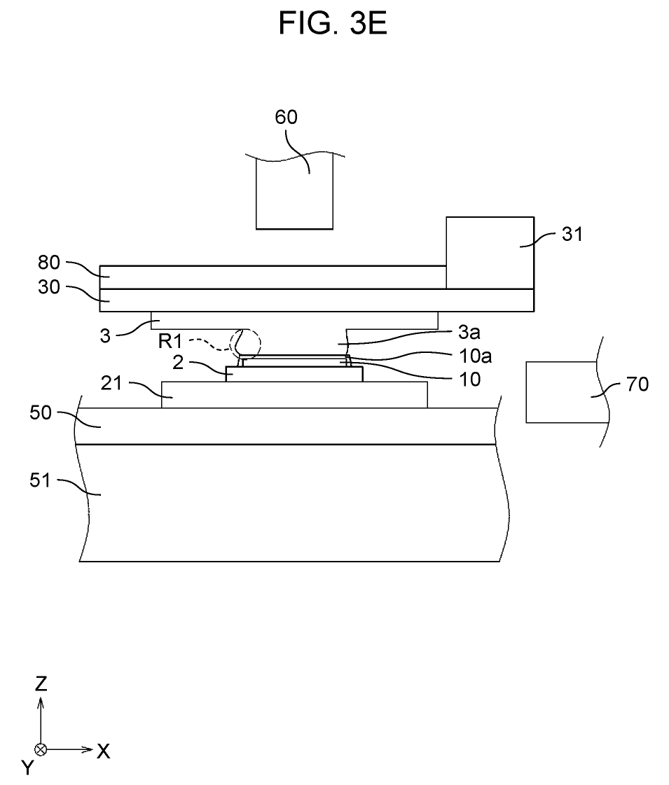

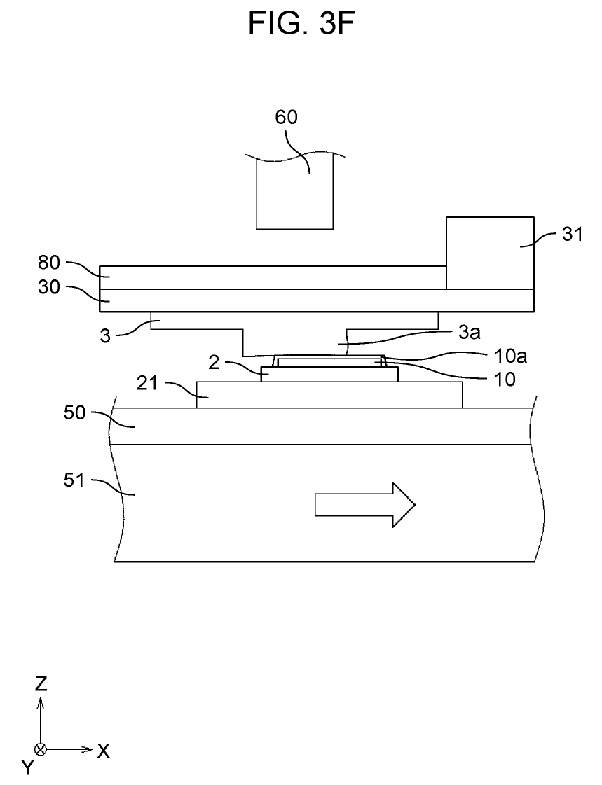

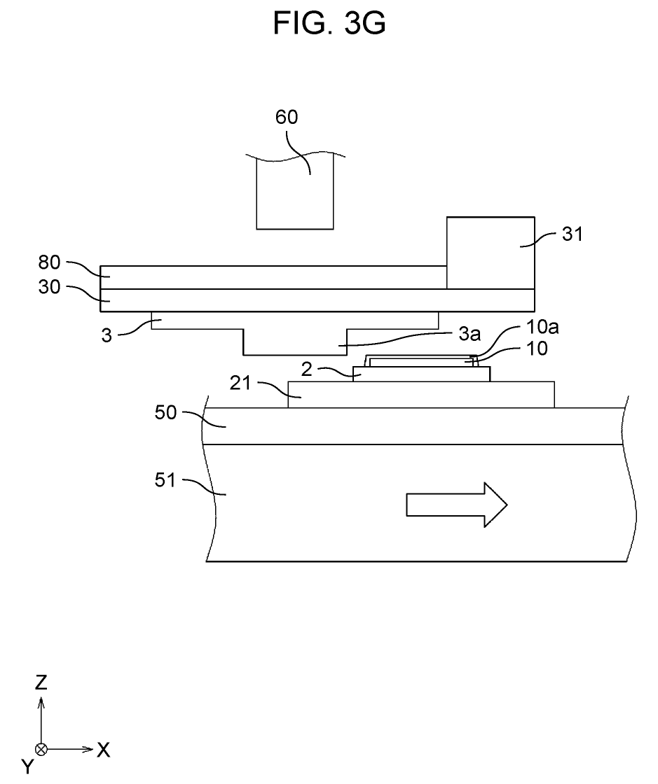

As illustrated in FIG. 3A to be described later, stamp 3 according to the present exemplary embodiment includes a front surface that partially protrudes forming central part 3a. Central part 3a is a protrusion provided on the surface facing element 10. Stamp 3 provided with central part 3a of the protrusion enables preventing another element formed on source substrate 1 from coming into contact with stamp 3 and being picked up by mistake when element 10 formed on source substrate 1 is picked up onto stamp 3. Central part 3a can be formed identical in shape to element 10 to be picked up in plan view, that is, formed in a shape having dimensions in the X-axis direction and the Y-axis direction that are equal to those of element 10, for example. Central part 3a may be larger or smaller in dimension than element 10 in the X-axis direction and the Y-axis direction. Central part 3a has a size of the protrusion, that is, a dimension of central part 3a in the Z-axis direction, which can be twice or more a dimension (thickness) of element 10 in the Z-axis direction, for example. When the dimension of central part 3a in the Z-axis direction is twice or more the thickness of element 10, another element can be prevented from being picked up at the time of contact between element 10 and stamp 3.

### Stamp head

Stamp head 30 is a member for holding stamp 3. Stamp head 30 is a quadrangular plate-like table, for example. Stamp head 30 is not limited in type as long as it can hold stamp 3. For example, stamp head 30 may be provided with a suction hole (not illustrated) for sucking stamp 3. When negative pressure is applied to the suction hole, stamp 3 can be brought into close contact with stamp head 30.

### Frame

Frame 40 is a member for holding stamp head 30. Frame 40 is configured to hold stamp head 30 with stamp 3 facing target substrate installation base 21. As illustrated in FIG. 1, frame 40 according to the present exemplary embodiment includes top plate 40b horizontal to the XY plane, and leg parts 40c extending from top plate 40b in the Z-axis direction. Top plate 40b of frame 40 includes through-hole 40a provided near its center. When through-hole 40a is provided in top plate 40b, source substrate 1, target substrate 2, and element 10 can be observed from above top plate 40b. This configuration enables facilitating alignment when element 10 is picked up from source substrate 1 and when element 10 is disposed on target substrate 2. Frame 40 can be made of stainless steel or the like, for example. Alternatively, frame 40 can be made of a material having transparency to enable observing source substrate 1, target substrate 2, and element 10 from above frame 40 without providing through-hole 40a.

### Position adjustment device

The position adjustment device including stamp head adjustment device 31 and substrate adjustment device 51 is for relatively moving target substrate 2 with respect to stamp 3. The present exemplary embodiment enables target substrate 2 to be moved relatively with respect to stamp 3 by moving stamp head 30 using stamp head adjustment device 31, moving substrate stage 50, on which target substrate 2 is placed, using substrate adjustment device 51, or moving both stamp head 30 and substrate stage 50 using stamp head adjustment device 31 and substrate adjustment device 51.

Stamp head adjustment device 31 is a movable stage for adjusting position of stamp head 30. Stamp head adjustment device 31 can move position of stamp head 30 in the X-axis direction, the Y-axis direction, and the Z-axis direction. Stamp head adjustment device 31 also can rotate stamp head 30 about the X-axis, the Y-axis, and the Z-axis. Stamp head adjustment device 31 can be fabricated by combining a linear motion stage using a linear ball guide, a gonio stage, or the like, for example. Stamp head adjustment device 31 is also provided with a motor and an encoder (not illustrated). Stamp head adjustment device 31 inputs position information to controller C1 described later, the position information being detected by the encoder.

Substrate adjustment device 51 is a movable stage for adjusting position of substrate stage 50. Substrate adjustment device 51 can move position of substrate stage 50 in the X-axis direction, the Y-axis direction, and the Z-axis direction. Substrate adjustment device 51 can rotate substrate stage 50 about the X axis, the Y axis, and the Z axis. Substrate adjustment device 51 can be fabricated by combining a linear motion stage using a linear ball guide, a gonio stage, or the like, for example. Substrate adjustment device 51 is also provided with a motor and an encoder (not illustrated). Substrate adjustment device 51 inputs position information to controller C1 described later, the position information being detected by the encoder.

The present exemplary embodiment uses substrate adjustment device 51 to bring target substrate 2 and stamp 3 relatively close to and separate from each other. Target substrate 2 and stamp 3 may be moved relatively by using stamp head adjustment device 31 or by using both stamp head adjustment device 31 and substrate adjustment device 51.

### First imaging unit

First imaging unit 60 images target substrate 2 and element 10 from above target substrate 2. First imaging unit 60 can also image source substrate 1 from above source substrate 1. First imaging unit 60 is disposed above through-hole 40a of frame 40. First imaging unit 60 is composed of a camera, for example. Information imaged by first imaging unit 60 is input to controller C1 described later.

### First imaging unit adjustment device

First imaging unit adjustment device 61 is a movable stage for adjusting position of first imaging unit 60. First imaging unit adjustment device 61 adjusts the position of first imaging unit 60 to enable first imaging unit 60 to image source substrate 1, target substrate 2, stamp 3, and element 10 from above. First imaging unit adjustment device 61 can move position of first imaging unit 60 in the X-axis direction, the Y-axis direction, and the Z-axis direction.

First imaging unit adjustment device 61 can be fabricated by combining a linear motion stage using a linear ball guide, or the like, for example. First imaging unit adjustment device 61 is also provided with a motor and an encoder (not illustrated). First imaging unit adjustment device 61 inputs position information to controller C1 described later, the position information being detected by the encoder.

### Second imaging unit

Second imaging unit 70 images target substrate 2 and element 10 from a lateral side of target substrate 2. Second imaging unit 70 can also image source substrate 1 from a lateral side of source substrate 1. Second imaging unit 70 is disposed from a lateral side of stamp head 30 and substrate stage 50. That is, second imaging unit 70 is disposed at a position along the X-axis direction or the Y-axis direction of stamp head 30 and substrate stage 50. Information imaged by second imaging unit 70 is input to controller C1 described later.

### Second imaging unit adjustment device

Second imaging unit adjustment device 71 is a movable stage for adjusting position of second imaging unit 70. Second imaging unit adjustment device 71 adjusts the position of second imaging unit 70 to enable second imaging unit 70 to observe source substrate 1, the target substrate 2, the stamp 3, and the element 10 from a lateral side. Second imaging unit adjustment device 71 can move position of second imaging unit 70 in the X-axis direction, the Y-axis direction, and the Z-axis direction.

Second imaging unit adjustment device 71 can be fabricated by combining a linear motion stage using a linear ball guide, or the like, for example. Second imaging unit adjustment device 71 is also provided with a motor and an encoder (not illustrated). Second imaging unit adjustment device 71 inputs position information to controller C1 described later, the position information being detected by the encoder.

### Contact detector

Contact detector 80 is disposed between stamp head 30 and frame 40 to detect contact between element 10 picked up on stamp 3 and target substrate 2. Contact detector 80 can also detect contact between element 10 formed on source substrate 1 and stamp 3. Contact detector 80 includes a piezoelectric force sensor, for example, and thus can detect the contact between element 10 and target substrate 2 by detecting pressure applied to stamp 3. Contact detector 80 is provided with three piezoelectric force sensors, for example, and thus can detect pressure applied to stamp 3 at positions of at least three points of stamp 3.

### Controller

Controller C1 controls operation of components of transfer device D1. Controller C1 is composed of a microcomputer or the like, for example. Controller C1 includes computing unit C2 that performs various calculations.

Controller C1 is capable of performing a step of transferring element 10 from source substrate 1 to target substrate 2 by controlling the position adjustment device, first imaging unit adjustment device 61, and second imaging unit adjustment device 71 based on the received position information and the like.

Controller C1 is also capable of receiving information such as images captured by first imaging unit 60 and second imaging unit 70. Controller C1 is capable of calculating (i) the amount of positional deviation between stamp 3 and element 10 when element 10 is picked up, and (ii) the amount of positional deviation between element 10 picked up on stamp 3 and target substrate 2, based on the image captured by first imaging unit 60, for example. Similarly, controller C1 is also capable of calculating (i) the amount of positional deviation between stamp 3 and element 10 when element 10 is picked up, and (ii) the amount of positional deviation between element 10 picked up on stamp 3 and target substrate 2, based on the image captured by second imaging unit 70. The amount of positional deviation is calculated by computing unit C2 of controller C1, for example.

Controller C1 controls the position adjustment device, that is, at least one of stamp head adjustment device 31 and substrate adjustment device 51, to reduce the amount of positional deviation calculated. For example, controller C1 controls the position adjustment device to bring stamp 3 and source substrate 1 relatively close to each other. When contact detector 80 detects that stamp 3 and element 10 formed on source substrate 1 come into contact with each other, controller C1 controls the position adjustment device to relatively separate stamp 3 and source substrate 1 from each other. Controller C1 further controls the position adjustment device to bring stamp 3 and target substrate 2 relatively close to each other. When contact detector 80 detects that element 10 picked up on stamp 3 and target substrate 2 come into contact with each other, controller C1 controls the position adjustment device to relatively separate stamp 3 and target substrate 2 from each other.

### Operation

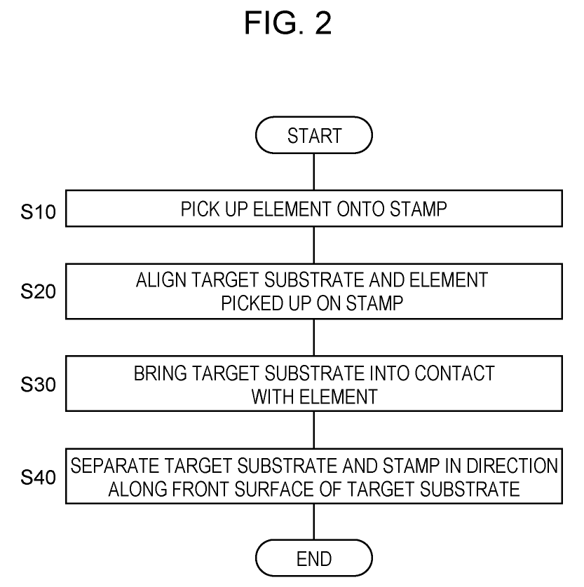

Next, a transfer method of element 10 using controller C1 will be described in detail. FIG. 2 is a flowchart for illustrating a transfer method for transferring element 10 picked up on stamp 3 to target substrate 2. FIGS. 3A to 3G are each a schematic diagram for illustrating the transfer method.

First, element 10 formed on source substrate 1 is picked up onto stamp 3 in S10. At this time, element 10 formed on source substrate 1 and stamp 3 are first aligned as illustrated in FIG. 3A. Element 10 and stamp 3 can be aligned by controlling substrate adjustment device 51 using controller C1 to move substrate stage 50 to a predetermined position on the XY plane, for example. The predetermined position of substrate stage 50 is a position where the alignment mark of element 10 formed on source substrate 1 and the alignment mark of stamp 3 align with each other, for example.

First imaging unit 60 images element 10 formed on source substrate 1 and stamp 3, and computing unit C2 of controller C1 calculates the amount of positional deviation between element 10 and stamp 3 based on imaged information. Controller C1 controls substrate adjustment device 51 to adjust position of substrate stage 50 based on the calculated amount of positional deviation. The position of substrate stage 50 is adjusted to adjust position of source substrate 1, thereby aligning element 10 formed on source substrate 1 with stamp 3. For the alignment, information imaged by second imaging unit 70 may be used.

Element 10 and stamp 3 are aligned on the order of nanometers or micrometers.

When element 10 and stamp 3 are aligned, stamp head adjustment device 31 may be controlled instead of substrate adjustment device 51 to move stamp head 30 in the XY directions, or both stamp head adjustment device 31 and substrate adjustment device 51 may be controlled.

After element 10 formed on source substrate 1 and stamp 3 are aligned, source substrate 1 and stamp 3 are brought relatively close to each other as illustrated in FIG. 3B. FIG. 3B shows an example in which controller C1 controls substrate adjustment device 51 to raise substrate stage 50 in the +Z-axis direction, thereby bringing source substrate 1 and stamp 3 relatively close to each other. Alternatively, source substrate 1 and stamp 3 may be brought relatively close to each other by controlling stamp head adjustment device 31 to lower stamp head 30 in the -Z-axis direction or by controlling both stamp head adjustment device 31 and substrate adjustment device 51.

Substrate stage 50 is raised to bring source substrate 1 and stamp 3 relatively close to each other to bring element 10 formed on source substrate 1 into contact with stamp 3. The contact between element 10 and stamp 3 can be detected by pressure applied to at least three points of stamp 3, the pressure being detected by contact detector 80, for example. When contact detector 80 detects that element 10 and stamp 3 have come into contact with each other, controller C1 stops substrate adjustment device 51 to stop raising of substrate stage 50.

The pressure applied to stamp 3 has a threshold value for detecting the contact between element 10 and stamp 3, the threshold value being set to an appropriate value in accordance with physical properties, shape, and the like of element 10 and stamp 3, for example. For example, when at least three piezoelectric force sensors are used, the contact made between element 10 and stamp 3 can be detected with a value detected by each piezoelectric force sensor, the value exceeding the threshold value set to from 1 [mN] to 10 [N] inclusive.

Controller C1 also controls substrate adjustment device 51 to raise substrate stage 50 at a speed from 1 [nm/sec] to 1000 [μm/sec] inclusive, for example.

To prevent substrate stage 50 from being excessively raised, the threshold value of the pressure detected by contact detector 80 may be set low, or the rising speed of substrate stage 50 may be set low.

After source substrate 1 and stamp 3 come into contact with each other, source substrate 1 and stamp 3 are relatively separated from each other as illustrated in FIG. 3C. When source substrate 1 and stamp 3 are relatively separated from each other after element 10 and stamp 3 are brought into contact with each other, element 10 is picked up onto stamp 3 using the adhesive force of stamp 3.

FIG. 3C shows an example in which controller C1 controls substrate adjustment device 51 to lower substrate stage 50 in the -Z-axis direction, thereby relatively separating source substrate 1 from stamp 3. Alternatively, source substrate 1 and stamp 3 may be relatively separated from each other by controlling stamp head adjustment device 31 to raise stamp head 30 in the +Z-axis direction or by controlling both stamp head adjustment device 31 and substrate adjustment device 51. At this time, element 10 is peeled off from source substrate 1 and picked up on stamp 3 using the adhesive force of stamp 3.

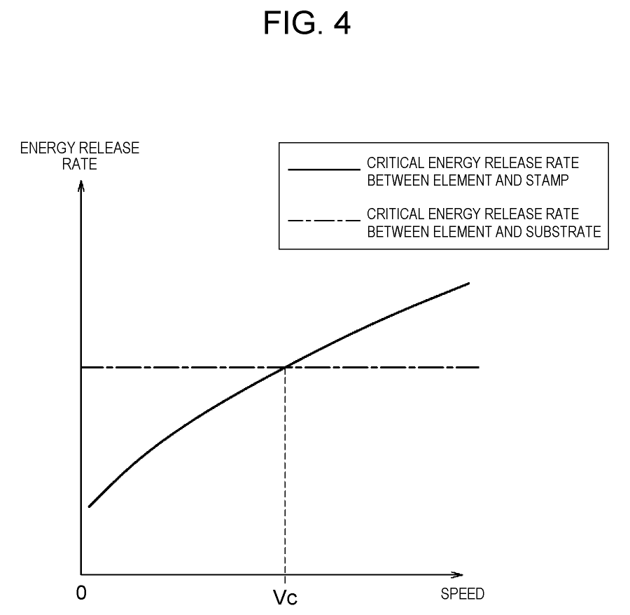

Controller C1 controls substrate adjustment device 51 to lower substrate stage 50 at a speed from 10 [μm/sec] to 1000 [mm/sec] inclusive, for example. The adhesive force of stamp 3 made of a viscoelastic material tends to increase depending on peeling speed in some speed regions. Thus, as lowering speed of substrate stage 50 is increased while element 10 and stamp 3 are in contact with each other, the adhesive force of stamp 3 is increased. Consequently, force for peeling element 10 from source substrate 1 increases to more than force for holding element 10 using source substrate 1. FIG. 4 is a graph for illustrating the adhesive force. As illustrated in FIG. 4, although a critical energy release rate between element 10 and the substrate (source substrate 1) is almost constant regardless of speed, the critical energy release rate between element 10 and stamp 3 increases in proportion to the speed. Thus, increasing the lowering speed of substrate stage 50 to faster than speed Vc illustrated in FIG. 4 enables the adhesive force acting on an interface between element 10 and stamp 3 to increase to more than the force for holding element 10 using source substrate 1. Consequently, controlling the lowering speed of substrate stage 50 enables element 10 to be easily picked up onto stamp 3.

After element 10 is picked up onto stamp 3, element 10 and target substrate 2 are aligned in step S20 as illustrated in FIG. 3D. In step S20, element 10 is aligned to be disposed at a desired position on target substrate 2. Element 10 can be aligned with target substrate 2 by controller C1 that controls the position adjustment device based on the image captured by first imaging unit 60 to change a relative position between stamp 3 and target substrate 2. Here, an example of alignment performed by controlling substrate adjustment device 51 among position adjustment devices will be described.

The alignment between element 10 and target substrate 2 is performed by controlling substrate adjustment device 51 using controller C1 to move substrate stage 50 to a predetermined position on the XY plane. The predetermined position is a position of substrate stage 50 in the XY plane, at which element 10 picked up on stamp 3 is aligned with a desired position of target substrate 2. The predetermined position can be defined by an alignment mark or the like provided on each of target substrate 2 and element 10.

First imaging unit 60 images target substrate 2 and element 10 picked up on stamp 3, and computing unit C2 of controller C1 calculates the amount of positional deviation between target substrate 2 and element 10 based on imaged information. Controller C1 controls substrate adjustment device 51 to adjust position of substrate stage 50 based on the calculated amount of positional deviation. The position of substrate stage 50 is adjusted to adjust position of target substrate 2, thereby aligning target substrate 2 with element 10. For the alignment, information imaged by second imaging unit 70 may be used.

In step S20, target substrate 2 and element 10 can be aligned on the order of nanometers or micrometers.

Next, controller C1 controls the position adjustment device to bring stamp 3 and target substrate 2 relatively close to each other to bring element 10 picked up on stamp 3 and target substrate 2 into contact with each other in step S30 as illustrated in FIG. 3E. For example, when stamp head 30 is lowered in the -Z-axis direction by stamp head adjustment device 31 or substrate stage 50 is raised in the +Z-axis direction by substrate adjustment device 51, element 10 picked up on stamp 3 and target substrate 2 can be brought into contact with each other. FIG. 3E shows an example in which substrate adjustment device 51 raises substrate stage 50 in the +Z-axis direction to bring stamp 3 and target substrate 2 relatively close to each other. That is, the example of FIG. 3E shows that target substrate 2 is raised in the +Z-axis direction to bring element 10 picked up on stamp 3 into contact with target substrate 2. When contact detector 80 detects that element 10 picked up on stamp 3 and target substrate 2 have come into contact with each other, controller C1 stops substrate adjustment device 51 to stop raising of substrate stage 50.

The pressure applied to stamp 3 has a threshold value for detecting the contact between element 10 picked up on stamp 3 and target substrate 2, the threshold value being set to an appropriate value in accordance with physical properties, shape, and the like of target substrate 2, stamp 3, and element 10, for example. For example, when at least three piezoelectric force sensors are used, the contact made between element 10 picked up on stamp 3 and target substrate 2 can be detected with a value detected by each piezoelectric force sensor, the value exceeding the threshold value set to from 1 [mN] to 10 [N] inclusive.

Controller C1 according to the present exemplary embodiment controls substrate adjustment device 51 to raise substrate stage 50 at a speed from 1 [nm/sec] to 1000 [μm/sec] inclusive, for example.

To prevent substrate stage 50 from being excessively raised, the threshold value of the pressure detected by contact detector 80 may be set low, or the rising speed of substrate stage 50 may be set low.

Even when element 10 is aligned with target substrate 2 in step S20, position of stamp 3 having picked up element 10 is less likely to completely align with position of target substrate 2 due to limitations of processing accuracy and machine accuracy. Thus, when element 10 and target substrate 2 come into contact with each other, stamp 3 is inclined relative to target substrate 2 as illustrated in FIG. 3E. Due to the relative inclination of stamp 3 with respect to target substrate 2, when element 10 and target substrate 2 come into contact with each other, stamp 3 having viscoelasticity is distorted in shape as illustrated in FIG. 3E.

Next, target substrate 2 and stamp 3 are relatively moved and separated in a direction along a front surface of target substrate 2 while target substrate 2 and element 10 are in contact with each other in step S40. The direction along the front surface of target substrate 2 is along an arrow in FIG. 3F, and is substantially horizontal to the XY plane.

After element 10 picked up on stamp 3 is brought into contact with target substrate 2, stamp 3 and target substrate 2 are separated from each other to transfer element 10 to target substrate 2. Element 10 is picked up on stamp 3 using adhesive force. The adhesive force acting on an interface between element 10 and stamp 3 is mainly caused by van der Waals force. Element 10 is brought into contact with target substrate 2, and then target substrate 2 and stamp 3 are relatively moved in the direction along the front surface of target substrate 2 to be separated from each other, thereby breaking van der Waals coupling between element 10 and stamp 3 to transfer element 10 from stamp 3 to target substrate 2.

The van der Waals coupling between stamp 3 and element 10 is more likely to be broken when a shear force is applied in a direction along the front surface of target substrate 2 than when a tensile force is applied in a direction in which stamp 3 and target substrate 2 face each other. Thus, target substrate 2 and stamp 3 are relatively moved in the direction along the front surface of target substrate 2 to relatively separate target substrate 2 from stamp 3 in step S40.

In step S40, controller C1 determines a relative movement direction between target substrate 2 and stamp 3 in the direction along the front surface of target substrate 2 based on distortion information on stamp 3 while element 10 and target substrate 2 are in contact with each other.

The distortion information on stamp 3 includes the amount of deformation of shape of stamp 3 and a relative amount of inclination of stamp 3 with respect to target substrate 2. Specifically, the distortion information on stamp 3 includes distribution information in the XY plane regarding the amount of distortion of stamp 3, that is, the amount of deformation of stamp 3 in the Z-axis direction. The distortion information on stamp 3 may be interpreted as relative inclination information between stamp 3 and target substrate 2. FIG. 3E shows an example in which distortion occurs in a part of region R1 of stamp 3, the part being surrounded by a broken line. The distortion of stamp 3 occurs due to the inclination of stamp 3 with respect to target substrate 2.

The distortion information on stamp 3 is calculated by controller C1 based on an image captured by first imaging unit 60, for example. For example, the distortion information can be calculated by comparing images captured by first imaging unit 60 before and after stamp 3 and target substrate 2 are brought close to each other in step S30, thereby calculating the amount of deformation of stamp 3.

Alternatively, the distortion information can be calculated by calculating the amount of distortion of stamp 3 based on pressure applied to stamp 3 at positions of at least three points of stamp 3 detected by contact detector 80. For example, the amount of distortion ε of stamp 3 can be calculated according to ε = F/(A × E), where pressure applied to stamp 3 detected by contact detector 80 is F, a sectional area of stamp 3 parallel to the XY plane is A, and an elastic modulus of stamp is E.

Controller C1 determines a relative movement direction between target substrate 2 and stamp 3 to separate a part with a large distortion of stamp 3 from target substrate 2 earlier than a part with a small distortion of stamp 3. Specifically, region R1 of stamp 3 is the part that has a larger distortion than other parts of stamp 3 in FIG. 3E.

The distortion or inclination of stamp 3 causes a difference in balance of forces acting on the interface between stamp 3 and element 10, including van der Waals force. Region R1 of stamp 3 has a larger distortion than the other parts of stamp 3, and thus has a stronger force acting on the interface than the other parts. Thus, when target substrate 2 is relatively moved in a direction away from region R1 of stamp 3, target substrate 2 and stamp 3 can be separated releasing the force acting on the interface.

As illustrated in FIGS. 3F to 3G, controller C1 controls substrate adjustment device 51 to move substrate stage 50 in the direction of the arrow, thereby separating target substrate 2 from stamp 3. At this time, the force acting on the interface between target substrate 2 and element 10 is larger than the force acting on the interface between stamp 3 and element 10, and thus element 10 is transferred to target substrate 2.

In general, the adhesive force acting on the interface between stamp 3 and element 10 tends to increase depending on peeling speed in some speed regions. As illustrated in FIG. 4, the critical energy release rate between source substrate 1 or target substrate 2 and element 10 is substantially constant. Meanwhile, the critical energy release rate between element 10 and stamp 3 tends to decrease as speed decreases. Thus, when a relative separation speed between target substrate 2 and stamp 3 is set to from 1 [μm/sec] to 100 [mm/sec] inclusive, for example, element 10 is easily peeled off from stamp 3 to more facilitate transfer of element 10 to target substrate 2.

As described above, controlling the relative movement direction between target substrate 2 and stamp 3 enables element 10 picked up on stamp 3 to be more easily transferred to target substrate 2. Additionally, controlling the separation speed between target substrate 2 and stamp 3 enables element 10 to be easily transferred to target substrate 2 with high production efficiency.

### Effect

The exemplary embodiment described above enables achieving effects below.

When target substrate 2 and stamp 3 are relatively moved in the direction along the front surface of target substrate 2, the adhesive force acting on the interface between stamp 3 and element 10 becomes smaller than the force acting on the interface between target substrate 2 and element 10. Thus, element 10 can be more easily transferred from stamp 3 to target substrate 2 with high production efficiency. Additionally, transfer device D1 can have a simple configuration.

### Second exemplary embodiment

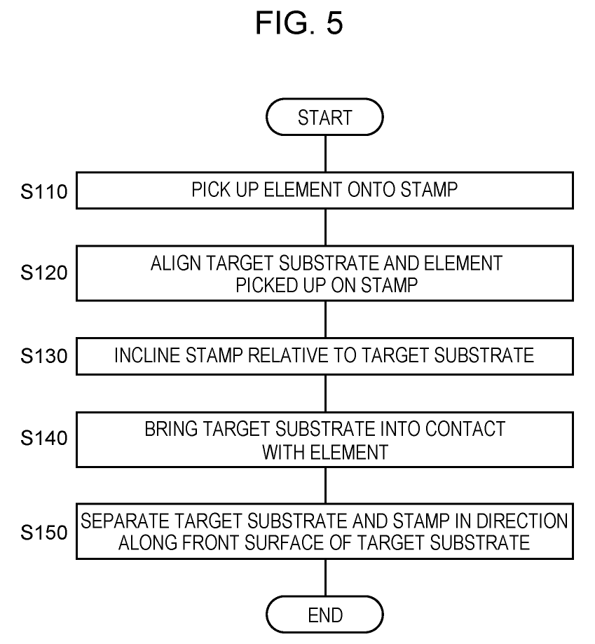

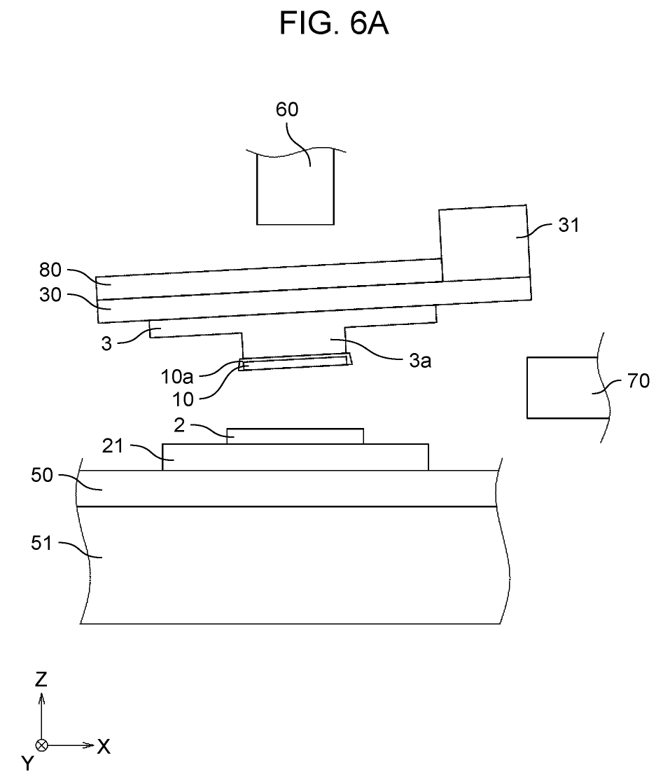

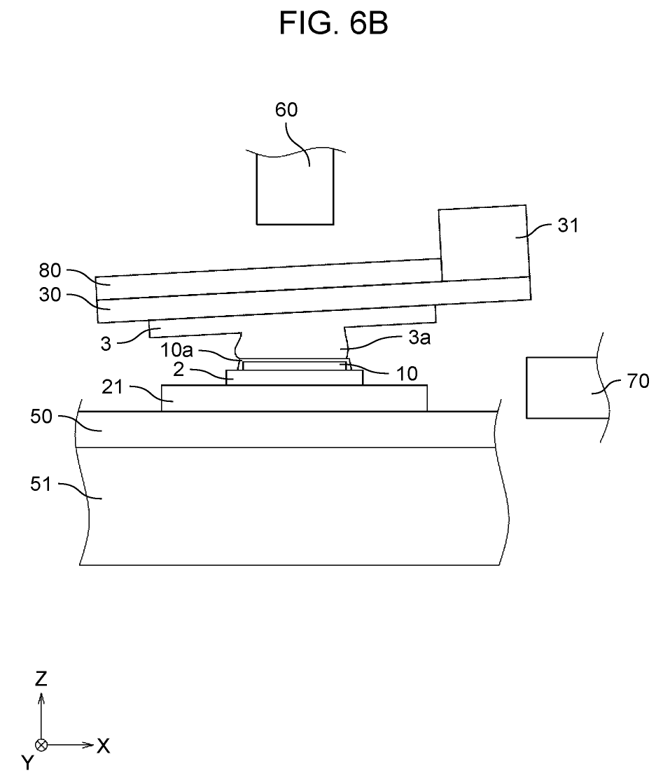

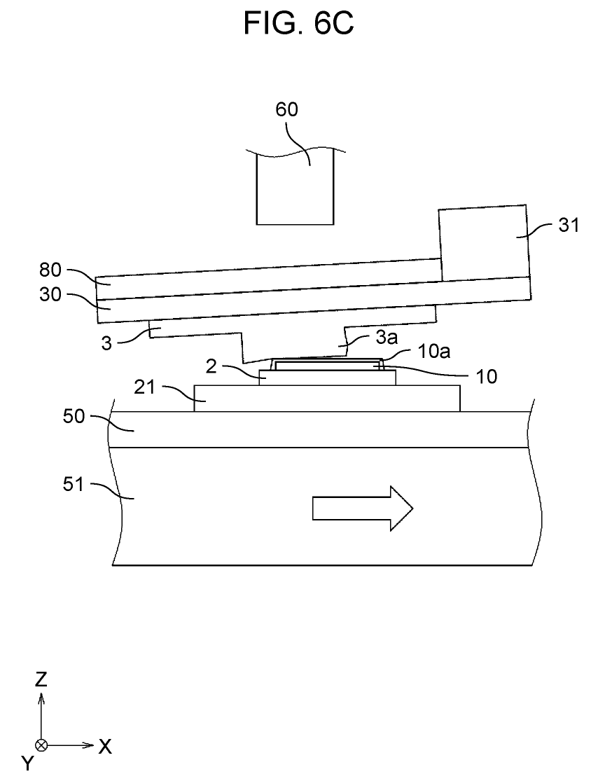

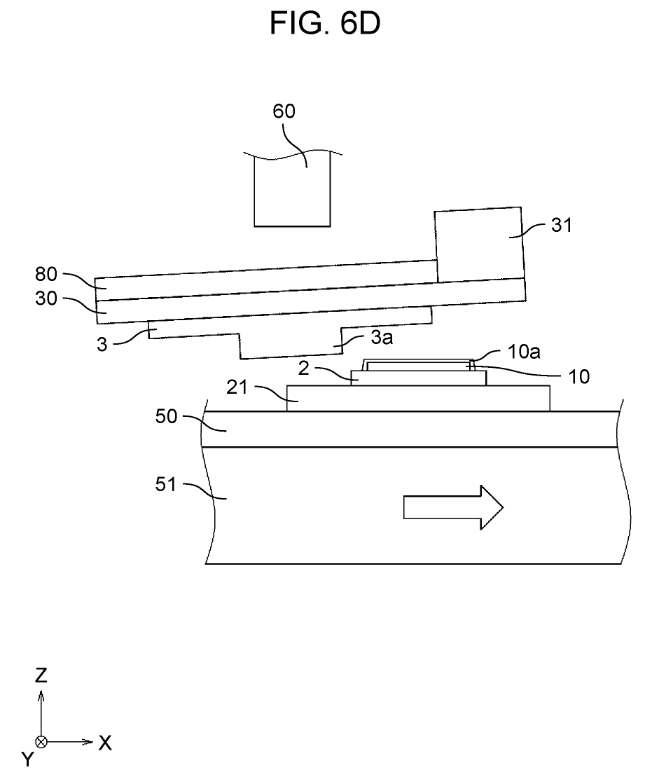

With reference to FIGS. 5 to 6D, a second exemplary embodiment will be described. The second exemplary embodiment includes components identical or equivalent to those in the first exemplary embodiment, the components being denoted by the same reference marks as those in the first exemplary embodiment. Duplicate description of the first exemplary embodiment will not be described in the second exemplary embodiment.

FIG. 5 is a flowchart for illustrating a transfer method of element 10 according to the second exemplary embodiment. FIGS. 6A to 6D are each a schematic view for illustrating the transfer method according to the second exemplary embodiment. As illustrated in FIG. 5, the second exemplary embodiment is different from the first exemplary embodiment in that the transfer method includes a step of inclining a stamp relative to a target substrate. Transfer device D1 is similar in configuration to that of the first exemplary embodiment, and thus the configuration is not described.

The first exemplary embodiment has been described in which the relative movement direction between target substrate 2 and stamp 3 is determined after element 10 picked up on stamp 3 comes into contact with target substrate 2. In the present exemplary embodiment, stamp 3 is inclined relative to target substrate 2 in advance before element 10 picked up on stamp 3 and target substrate 2 come into contact with each other. Relatively inclining stamp 3 in advance enables determining the relative movement direction between target substrate 2 and stamp 3 in advance. Steps S110 to S120 illustrated in FIG. 5 are similar to steps S10 to S20 described in the first exemplary embodiment, and thus will not be described.

After element 10 picked up on stamp 3 and target substrate 2 are aligned in step S120, stamp 3 is inclined relative to target substrate 2 in step S130. In the present exemplary embodiment, controller C1 controls stamp head adjustment device 31 among position adjustment devices to incline stamp head 30, thereby inclining stamp 3 relative to target substrate 2. Stamp 3 may be inclined relative to target substrate 2 by controlling substrate adjustment device 51 or by controlling both stamp head adjustment device 31 and substrate adjustment device 51.

The inclination of stamp 3 relative to target substrate 2 can be determined based on information imaged by first imaging unit 60. Alternatively, stamp 3 may be inclined in a predetermined direction regardless of the information imaged. Stamp 3 has an inclination angle with respect to target substrate 2, the inclination angle being able to be set to an appropriate value in accordance with physical properties or shapes of element 10 and target substrate 2. When the inclination angle of stamp 3 with respect to target substrate 2 is set to 10 degrees or less with respect to the front surface of target substrate 2, for example, stamp 3 can be prevented from coming into contact with target substrate 2, thereby preventing target substrate 2 from being contaminated and element 10 from being subjected to an excessive force and damaged. The inclination angle of stamp 3 with respect to target substrate 2 is more preferably 5 degrees or less with respect to the front surface of target substrate 2. As illustrated in FIG. 6A, controller C1 controls stamp head adjustment device 31 to incline stamp head 30 at a predetermined angle in at least one of the X-axis direction and the Y-axis direction.

As illustrated in FIG. 6B, controller C1 controls substrate adjustment device 51 to raise substrate stage 50 in the +Z-axis direction while stamp head 30 is inclined in step S140. Stamp head 30 is inclined, so that element 10 picked up on stamp 3 and target substrate 2 come into contact with each other while stamp 3 is inclined with respect to target substrate 2.

Next, target substrate 2 and stamp 3 are relatively separated from each other in step S150 as illustrated in FIGS. 6C to 6D. In the present exemplary embodiment, target substrate 2 and stamp 3 are relatively separated by controlling substrate adjustment device 51 to move substrate stage 50. Substrate stage 50 is moved in a direction that can be determined in advance by controller C1 based on the inclination of stamp head 30 in step S130, that is, the inclination of stamp 3 relative to target substrate 2.

When any of the exemplary embodiments or modifications among the various exemplary embodiments or modifications described above are combined, effects of each of the combined exemplary embodiments or modifications can be achieved. The exemplary embodiments or the examples may be combined with each other, and any of the exemplary embodiments may be combined with any of the examples. Then, features in different exemplary embodiments or examples can be combined with each other.

Although the present disclosure has been fully described in connection with preferable exemplary embodiments with reference to the accompanying drawings, various modifications or corrections are obvious to those skilled in the art. Such modifications or corrections are to be understood as being included within the scope of the present disclosure as set forth in the appended scope of claims, insofar as the modifications or corrections do not depart from the scope of the present disclosure. Additionally, combinations or changes in order of elements in the exemplary embodiments can be achieved without departing from the scope and spirit of the present disclosure.

### Appendix

The above description of the exemplary embodiments discloses the following techniques.

### Technique 1

A transfer method for transferring an element to a front surface of a target substrate using a stamp having adhesiveness, the transfer method including: aligning the target substrate and the element picked up on the stamp by an adhesive force of the stamp; bringing the target substrate and the stamp relatively close to each other to bring the target substrate and the element into contact with each other; and moving the target substrate and the stamp relatively in a direction along a front surface of the target substrate to separate the target substrate and the stamp from each other while the target substrate and the element are in contact with each other.

This kind of method enables providing a transfer method of an element, the transfer method being capable of improving production efficiency with a simple configuration.

### Technique 2

The transfer method described in Technique 1, in which the moving the target substrate and the stamp relatively in the direction along the front surface of the target substrate to separate the target substrate and the stamp from each other while the target substrate and the element picked up on the stamp are in contact with each other includes determining a relative movement direction between the target substrate and the stamp based on distortion information on the stamp while the element picked up on the stamp and the target substrate are in contact with each other.

This kind of method enables reducing the adhesive force between the stamp and the element to smaller than a bonding force between the element and the target substrate, so that the element can be easily transferred to the target substrate.

### Technique 3

The transfer method described in Technique 1 or 2, in which the distortion information on the stamp is calculated based on pressure applied to the stamp at positions of at least three points of the stamp.

This kind of method enables calculating the distortion information on the stamp more accurately.

### Technique 4

The transfer method described in Technique 1 or 2, in which the distortion information on the stamp is calculated based on the amount of deformation of an outer edge part of the stamp.

This kind of method enables calculating the distortion information on the stamp more accurately.

### Technique 5

The transfer method described in any one of Techniques 1 to 4, in which the distortion information on the stamp includes an amount of distortion of the stamp, and determining the relative movement direction between the target substrate and the stamp based on the distortion information on the stamp includes determining a movement direction so as to separate a part with a large distortion of the stamp from the target substrate earlier than a part with a small distortion of the stamp.

This kind of method enables reducing the adhesive force between the stamp and the element to smaller than a bonding force between the element and the target substrate, so that the element can be easily transferred to the target substrate.

### Technique 6

The transfer method described in any one of Techniques 1 to 4, further including the inclining the stamp relative to the target substrate before the bringing the target substrate and the stamp relatively close to each other to bring the target substrate and the element into contact with each other.

This kind of method enables determining a moving method for relatively separating the target substrate and the stamp in advance, so that the production efficiency can be further improved.

### Technique 7

The transfer method described in any one of Techniques 1 to 6, further including the bringing a source substrate provided with the element relatively close to the stamp and separate from the stamp to pick up the element formed on the source substrate onto the stamp using the adhesive force of the stamp before the aligning the target substrate and the element picked up on the stamp by the adhesive force of the stamp.

This kind of method enables performing a process from pickup of the element to transfer to the target substrate continuously.

### Technique 8

A transfer device for transferring an element to a front surface of a target substrate using a stamp having adhesiveness, the transfer device including: a target substrate installation base on which the target substrate is installed; a stamp head having a stamp for picking up the element by an adhesive force; a frame for holding the stamp head so that the stamp faces the target substrate installation base; a position adjustment device that brings the target substrate and the stamp relatively close to each other and separate from each other; a first imaging unit that images the target substrate and the element from above the target substrate; a controller that controls the position adjustment device and the first imaging unit; and a contact detector that detects contact between the target substrate and the element, in which the controller detects not only the amount of positional deviation between the element and the target substrate based on an image captured by the first imaging unit, but also distortion information on the stamp when the target substrate and the element picked up on the stamp are in contact with each other, the controller controls the position adjustment device to bring the target substrate and the stamp close to each other by relatively moving the target substrate and the stamp to reduce the amount of positional deviation, and the controller controls the position adjustment device to relatively move the target substrate and the stamp to separate the target substrate and the stamp from each other in a direction along a front surface of the target substrate while the target substrate and the element are in contact with each other when the contact detector detects the contact between the target substrate and the element picked up on the stamp.

This kind of configuration enables providing a transfer device of an element, the transfer device being capable of improving production efficiency with a simple configuration.

### Technique 9

The transfer device described in Technique 8, in which the contact detector includes at least three pressure sensors for measuring pressure applied to the stamp, and the controller calculates distortion information on the stamp based on detection values of the at least three pressure sensors.

This kind of configuration enables calculating the distortion information on the stamp more accurately.

### Technique 10

The transfer device described in Technique 8 or 9, in which the controller calculates the amount of deformation of an outer edge part of the stamp based on the image captured by the first imaging unit, and calculates the distortion information on the stamp based on the amount of deformation of the outer edge part of the stamp.

This kind of configuration enables calculating the distortion information on the stamp more accurately.

### Technique 11

The transfer device described in any one of Techniques 8 to 10, further including a second imaging unit that images the target substrate and the element from a lateral side of the target substrate, in which the controller calculates the amount of deformation of an outer edge part of the stamp based on an image captured by the second imaging unit, and calculates the distortion information on the stamp based on the amount of deformation of the outer edge part of the stamp.

This kind of configuration enables calculating the distortion information on the stamp more accurately.

### Technique 12

The transfer device described in any one of Techniques 8 to 11, in which the controller determines a relative movement direction between the target substrate and the stamp based on the distortion information on the stamp.

This kind of configuration enables reducing the adhesive force between the stamp and the element to smaller than a bonding force between the element and the target substrate, so that the element can be easily transferred to the target substrate.

### Technique 13

The transfer device described in any one of Techniques 8 to 11, in which the controller controls the position adjustment device to incline the target substrate relative to the stamp before the target substrate and the element picked up on the stamp come into contact with each other.

This kind of configuration enables performing a process from pickup of the element to transfer to the target substrate continuously.

### Technique 14

The transfer device described in any one of Techniques 8 to 13, further including a source substrate installation base on which a source substrate provided with the element is installed, in which the source substrate installation base holds the source substrate so that a front surface of the source substrate faces the same direction as the front surface of the target substrate, the position adjustment device moves the source substrate relative to the stamp, the contact detector detects contact between the element formed on the source substrate and the stamp, and the controller controls the position adjustment device to bring the source substrate relatively close to the stamp and separate from the stamp to pick up the element formed on the source substrate onto the stamp using the adhesive force of the stamp.

This kind of configuration enables performing a process from pickup of the element to transfer to the target substrate continuously.

The present disclosure enables providing a transfer method and a transfer device that are capable of improving production efficiency with a simple configuration.

The present disclosure is useful in the fields of high-speed optical communication typified by a micro LED display or silicon photonics, high-precision sensing using laser light, and the like.

What is claimed is:

1. A transfer method for transferring an element to a front surface of a target substrate using a stamp having adhesiveness, the transfer method comprising:
aligning the target substrate and the element picked up on the stamp by an adhesive force of the stamp;
bringing the target substrate and the stamp relatively close to each other to bring the target substrate and the element into contact with each other; and
moving the target substrate and the stamp relatively in a direction along a front surface of the target substrate to separate the target substrate and the stamp from each other while the target substrate and the element are in contact with each other.

2. The transfer method according to claim 1, wherein the moving the target substrate and the stamp relatively in the direction along the front surface of the target substrate to separate the target substrate and the stamp from each other while the target substrate and the element picked up on the stamp are in contact with each other includes determining a relative movement direction between the target substrate and the stamp based on distortion information on the stamp while the element picked up on the stamp and the target substrate are in contact with each other.

3. The transfer method according to claim 2, wherein the distortion information on the stamp is calculated based on pressure applied to the stamp at positions of at least three points of the stamp.

4. The transfer method according to claim 2, wherein the distortion information on the stamp is calculated based on an amount of deformation of an outer edge part of the stamp.

5. The transfer method according to claim 2, wherein
the distortion information on the stamp includes an amount of distortion of the stamp, and
determining the relative movement direction between the target substrate and the stamp based on the distortion information on the stamp includes determining a movement direction so as to separate a part with a large distortion of the stamp from the target substrate earlier than a part with a small distortion of the stamp.

6. The transfer method according to claim 1, further comprising inclining the stamp relative to the target substrate before the bringing the target substrate and the stamp relatively close to each other to bring the target substrate and the element into contact with each other.

7. The transfer method according to claim 1, further comprising bringing a source substrate provided with the element relatively close to the stamp and separate from the stamp to pick up the element formed on the source substrate onto the stamp using the adhesive force of the stamp before the aligning the target substrate and the element picked up on the stamp by the adhesive force of the stamp.

8. A transfer device for transferring an element to a front surface of a target substrate using a stamp having adhesiveness, the transfer device comprising:
a target substrate installation base on which the target substrate is installed;
a stamp head having a stamp for picking up the element by an adhesive force;
a frame for holding the stamp head so that the stamp faces the target substrate installation base;
a position adjustment device that brings the target substrate and the stamp relatively close to each other and separate from each other;
a first imaging unit that images the target substrate and the element from above the target substrate;
a controller that controls the position adjustment device and the first imaging unit; and
a contact detector that detects contact between the target substrate and the element,
wherein
the controller detects not only an amount of positional deviation between the element and the target substrate based on an image captured by the first imaging unit, but also distortion information on the stamp when the target substrate and the element picked up on the stamp are in contact with each other,
the controller controls the position adjustment device to bring the target substrate and the stamp close to each other by relatively moving the target substrate and the stamp to reduce the amount of positional deviation, and
the controller controls the position adjustment device to relatively move the target substrate and the stamp to separate the target substrate and the stamp from each other in a direction along a front surface of the target substrate while the target substrate and the element are in contact with each other when the contact detector detects the contact between the target substrate and the element picked up on the stamp.

9. The transfer device according to claim 8, wherein
the contact detector includes at least three pressure sensors for measuring pressure applied to the stamp, and
the controller calculates distortion information on the stamp based on detection values of the at least three pressure sensors.

10. The transfer device according to claim 8, wherein the controller calculates an amount of deformation of an outer edge part of the stamp based on the image captured by the first imaging unit, and calculates the distortion information on the stamp based on the amount of deformation of the outer edge part of the stamp.

11. The transfer device according to claim 8, further comprising a second imaging unit that images the target substrate and the element from a lateral side of the target substrate,
wherein the controller calculates an amount of deformation of an outer edge part of the stamp based on an image captured by the second imaging unit, and calculates the distortion information on the stamp based on the amount of deformation of the outer edge part of the stamp.

12. The transfer device according to claim 8, wherein the controller determines a relative movement direction between the target substrate and the stamp based on the distortion information on the stamp.

13. The transfer device according to claim 8, wherein the controller controls the position adjustment device to incline the target substrate relative to the stamp before the target substrate and the element picked up on the stamp come into contact with each other.

14. The transfer device according to claim 8, further comprising
a source substrate installation base on which a source substrate provided with the element is installed,
wherein
the source substrate installation base holds the source substrate so that a front surface of the source substrate faces the same direction as the front surface of the target substrate,
the position adjustment device moves the source substrate relative to the stamp,
the contact detector detects contact between the element formed on the source substrate and the stamp, and
the controller controls the position adjustment device to bring the source substrate relatively close to the stamp and separate from the stamp to pick up the element formed on the source substrate onto the stamp using the adhesive force of the stamp.
